(19) United States
(12) Patent Application Publication
(10) Pub. No.: US 2014/0141674 A1
(43) Pub. Date: May 22, 2014

(54) APPARATUS AND METHODS FOR PLASMA ENHANCED CHEMICAL VAPOR DEPOSITION OF DIELECTRIC/POLYMER COATINGS

(71) Applicant: Liquipel IP, LLC, Santa Ana, CA (US)

(72) Inventors: Herbert Vincent Galbreath, Portola Hills, CA (US); Alexander Hill, South Coast Metro, CA (US); Daniel Storey, Longmont, CO (US); Demetrius Chrysostomou, Riverside, CA (US)

(21) Appl. No.: 14/079,911

(22) Filed: Nov. 14, 2013

Related U.S. Application Data
(63) Continuation-in-part of application No. 13/838,612, filed on Mar. 15, 2013.
(60) Provisional application No. 61/727,423, filed on Nov. 16, 2012.
(60) Provisional application No. 61/727,873, filed on Nov. 19, 2012.
(60) Provisional application No. 61/727,891, filed on Nov. 19, 2012.
(60) Provisional application No. 61/727,396, filed on Nov. 16, 2012.

(51) Int. Cl. C23C 16/515

(52) U.S. Cl. CPC C23C 16/515
USPC 442/231; 428/327; 442/379; 427/488

(57) ABSTRACT

Apparatuses and methods are described that involve the deposition of coatings on substrates. The polymer coatings generally comprise a wear resistant layer and/or a hydrophobic layer. The wear resistant layer can comprise a metal oxide or metal nitride. The hydrophobic layer can comprise fused polymer particles having an average primary particle diameter on the nanometer to micrometer scale. The coatings are deposited on substrates using specifically adapted plasma enhanced atomic layer deposition and plasma enhanced chemical vapor deposition approaches. The substrates can include computing devices and fabrics.

### CROSS REFERENCE TO RELATED APPLICATIONS

This application claims priority to U.S. provisional patent application Ser. No. 61/727,423 to Hill et al., filed Nov. 16, 2012; U.S. provisional patent application 61/727,873 to Storey, filed Nov. 19, 2012; and is a continuation-in-part of U.S. patent application Ser. No. 13/838,612 to Storey et al., filed Mar. 15, 2013, which claims priority to U.S. provisional patent application Ser. No. 61/727,891 to Chrysostomou et al., filed Nov. 19, 2012, and U.S. provisional patent application Ser. No. 61/727,396 to Hill et al., filed Nov. 16, 2012; all of which are incorporated herein by reference.

### BACKGROUND

Many coatings are known for adding water or wear resistance to a bulk material. These coatings range from familiarly known paints or waxes to high-technology chemical formulations. Chemical vapor deposition and plasma enhanced chemical vapor deposition are coating techniques that have been used to make coatings on surfaces, such as for semiconductor or high performance optical glasses.

### SUMMARY OF THE INVENTION

In a first aspect, the invention pertains to a method for forming a coating on a substrate. The method comprises sequentially exposing a substrate to an organometallic reactant and a dielectric forming reactant in the presence of a first plasma to form a wear resistant layer on a surface of the substrate, wherein the dielectric forming reactant is an oxygen donating or nitrogen donating reactant and polymerizing a vinyl monomer or epoxide monomer in the presence of a second plasma and the substrate comprising the wear resistant layer to form a hydrophobic polymer layer on the dielectric layer.

In another aspect, the invention pertains to a substrate comprising a transparent coating. The coating comprises a wear resistant layer comprising a metal/metalloid oxide or a metal/metalloid nitride; and a hydrophobic layer disposed on top the wear resistant layer, the hydrophobic layer comprising fused polymer particles having an average primary particle diameter of from about 20 nm to about 100 microns.

### BRIEF DESCRIPTION OF THE DRAWINGS

FIG. 1 is a drawing of schematic representation of a PEALD/PECVD apparatus.

FIG. 2 is a drawing of a schematic representation of a precursor delivery system.

FIG. 3 is a schematic representation of an electrolysis test configuration.

FIG. 4 is a graph showing plots of current versus time generated by electrolysis tests conducted on coated circuit boards and a non-coated circuit board.

FIG. 5 is a photographic image obtained during goniometric analysis of a water droplet on a coated circuit board substrate having a wear resistant layer deposited over 100 cycles.

FIG. 6 is a photographic image obtained during goniometric analysis of a water droplet on a coated circuit board substrate having a wear resistant layer deposited over 200 cycles.

FIG. 7 is a photographic image obtained during goniometric analysis of a water droplet on non-coated circuit board substrate.

FIG. 8 is a photographic image obtained during goniometric analysis of a water droplet on a coated woven material substrate.

FIG. 9 is a photographic image obtained during goniometric analysis of a water droplet on a coated non-woven material substrate.

### DETAILED DESCRIPTION

Described herein are apparatuses and methods for depositing protective coatings onto substrates. The coatings can surface modify the substrates to provide for desired levels of protection while allowing the substrates to substantially retain their inherent properties. Generally, the coatings comprise a wear resistant layer and a hydrophobic polymer layer. Although, in some embodiments, the coating can comprise either a wear resistant layer or a hydrophobic layer. The coatings can be desirably formed from adapted atomic layer deposition (“ALD”) and chemical vapor depositions approaches (“CVD”). In particular, adapted ALD/CVD incorporating plasma processing can be desirably used to deposit the coatings.

The coatings described herein can be deposited on a wide variety of substrates including, but not limited to substrates comprising glass, optical materials, fiber glass, building materials, natural materials (like leather), polymers, ceramics, woven textiles and non-woven fabrics. Woven fabrics generally refer to fabrics that are formed by weaving threads. Woven materials include, but are not limited to, technical cloths, leathers, and materials formed from wools, cottons, synthetics and blends. Non-woven fabrics generally refer to a fabric-like material made from long fibers, bonded together by chemical, mechanical, heat or solvent treatment. Non-wove materials include, but are not limited to, materials formed from felts, wools, and cottons. In general, the adapted processing approaches described herein are desirably mild such that a coating can be applied to a variety of substrates without damaging the substrate. The substrate may or may not have functionality beyond the bulk properties of the materials. In some embodiments, the coatings described herein are desirably benign to the functional properties of a substrate such that the functionality of the substrate is preserved after deposition of the coating. For example, in some embodiments, the substrate can comprise functional devices such as an electronic component, including but not limited to circuit boards and the like, as well as computing devices, including but not limited to laptop computers, tablet computers, mobile phones, portable music players and the like.

Moreover, the coatings can have high level of transparency and, therefore, can provide protection to a substrate in application settings where it is desirable to see the substrate through the polymer layer. For example, such application settings can involve the deposition of coatings on woven or non-woven fabrics and devices incorporating a display, including but not limited to computing devices, televisions, polymer and/or glass windows or coatings and the like.

The wear resistant layer can help to protect the substrate against physical damage including scratches and wearing due to abrasion and the like. In general, the wear-resistant layer comprises a metal or metalloid (“metal/metalloid”) oxide (including transition metals) or a metal/metalloid nitride. Metal/Metalloid oxide and nitride layers can be significantly harder than polymer layers and, therefore, can be better suited to provide protection against physical damage. Metalloids are elements that exhibit chemical properties intermediate between or inclusive of metals and nonmetals. Metalloid elements include silicon, boron, arsenic, antimony, and tellurium. Examples of desirable metal/metalloid oxide and metal/metalloid nitride compositions include, but are not limited to, aluminum oxide, chromium oxide, titanium oxide, zirconium oxide, aluminum nitride, hafnium nitride and chromium nitride.

The adapted plasma assisted ALD processing approaches described herein can provide for improved wear-resistant layers which can also be, to a relatively large extent, free from pin-hole structures through the wear resistant layer. Pin-hole structures comprise holes through the layer that can allow for passage of liquid through the layer to the underlying substrate such that layers having reduced pin-hole structures provide for improved hydrophobicity. However, in some embodiments, the reduced amount of pin-hole structures may not provide a desirable level of hydrophobicity and, therefore, in some embodiments it can be desirable for the coating to comprise an additional hydrophobic layer to provide improved hydrophobicity of the coating as a whole.

A hydrophobic layer can comprise a particulate layer that can help to prevent the passage of liquid the layer. The hydrophobicity of a coating can be measured by measuring the equilibrium contact angle of the liquid/vapor interface at the solid boundary between the coating and a drop of water at rest thereon. The contact angle is generally measured relative to an axis along planar surface of the coating and directed towards the center of the droplet with an origin at the point of contact between the water drop and the coating. Generally, larger contact angles reflect a more hydrophobic surface. A surface is considered hydrophilic when the water contact angle is smaller than 90°. The solid surface is considered hydrophobic when the water contact angle is from 90° to about 115°. A highly hydrophobic surface has a water contact angles of more than about 115° to about 150°. A super-hydrophobic surface has a water contact of more than 150°. In some embodiments, the hydrophobic layers described herein can have a contact angle with water of from about 90° to about 160° and, in further embodiments, from about 100° to about 150°, in further embodiments between 115° to about 150° and, in further embodiments, from about 130° to about 145°. A person of ordinary skill in the art will recognize additional water contact angle ranges within the explicitly recited ranges are contemplated and within the present disclosure. Contact angles can be measured optically by taking an optical image of a water droplet on a surface and measuring the contact angle between the water droplet and the surface. Optical contact angle analysis can be performed using commercially available goniometers such as the VCA Optima S goniometer (AST Products, Inc., Billerica, Mass.).

The hydrophobic layer can comprise a porous layer having polymer particles fused to the underlying substrate and/or a porous network of fused particles that is also fused to the substrate. The polymer particles can have a generally spherical shape. In general, polymer layers incorporating polymer particles are more hydrophobic relative to non-particulate polymer layers. While there are various mechanisms that can provide for varying degrees of polymer particle-particle fusing, without being limited by a theory, such mechanisms can include, but are not limited to, interdigitation of polymer chains between adjacent particles and/or cross-linking of polymers between adjacent particles. The polymer particles can have a range of average primary particle size from the nanometer scale to the micrometer scale. Primary particles diameter refers to the diameter of the unfused particles. The primary particle size can be determined form scanning electron microscopy (“SEM”) images taken of the deposited particulate layers. Although the deposited particles comprise particles that are fused to the underlying structure and/or to each other, the primary particle structure can still be estimated from the SEM images. The diameter of a particle is taken as the longest linear dimension of the deposited particle. In some embodiments, the polymer particles can have an average primary particle diameter of no more than about 10 μm; in further embodiments, no more than about 1 μm; in further embodiments, no more than about 200 nm; and in further embodiments from about 2 nm to about 50 nm. A person of ordinary skill in the art will recognize additional ranges within the explicitly recited ranges are contemplated and within the present disclosure.

The adapted plasma assisted CVD processing approaches described herein can provide for hydrophobic layers comprising polymer particles. The polymer particles comprise polymers having repeat subunits formed from monomers that are polymerized. The polymers may be cross-linked or not cross-linked, depending on the particular reaction and polymeric precursors that are used. The polymers in the particles can comprise at least 2, at least 100, at least 1000, at least 10000, at least 1,000,000 or more repeat subunits. The term monomer refers to a molecule group that can combine with others of the same kind to form a polymer. Vinylic and epoxide monomer groups are generally useful in plasma-based polymerization processes. The term vinylic refers to the functional group C═C and the term epoxide refers to the 3-membered cyclic ether COC, with the carbon atoms singly bonded to each other and the oxygen. The term group indicates that the generically recited chemical entity (e.g., alkyl group) may have any substituent thereon which is consistent with the bond structure of that group. For example, where the term ‘alkyl group’ is used, that term would not only include unsubstituted linear, branched and cyclic alkyls, such as methyl, ethyl, isopropyl, tert-butyl, cyclohexyl, dodecyl and the like, but also substituents having heteroatom such as 3-ethoxylpropyl, 4-(N-ethylamino)butyl, 3-hydroxypentyl, 2-thiolhexyl, 1,2,3-tribromopropyl, and the like. However, as is consistent with such nomenclature, no substitution would be included within the term that would alter the fundamental bond structure of the underlying group.

In some embodiments, the coating can comprise either a wear resistant layer or a hydrophobic layer. The desirability of each coating can depend upon the particular application and, therefore, in some embodiments a coating having only a wear resistant layer or only a hydrophobic layer can be desirable. For example, for some coating applications involving mobile phone screens, eyeglasses, windshields, shoes and the like, added wear resistance may be desired, but not a relatively high level of added hydrophobic protection. In such application settings, the coating can desirably comprise only the wear-resistant layer. For other coating applications, such as those involving internal electronic components, a relatively high level of added hydrophobic protection may be desired, but not added wear-resistance. In such application settings, the hydrophobic layer alone may provide desirable protection.

A layer in a coating has contact with another layer in the coating and/or the substrate. The contact between the layers and/or the substrate can be complete or partial. The coating may be discontinuous with a surface at some points and still retain its characteristic as a coating. In general, however, coatings that are free of defects may be made using the plasma-based processes described herein, so that the coatings, or a layer of a coating, may be effectively continuous with respect to the wear-resistant and/or hydrophobic properties of the layer and/or be free of pinholes and/or free of electrically-detectable gaps. Coatings, and layers, can have a selected thickness, selected composition, variable chemical properties based on the teachings herein. Coatings, and layers, may cover all or a portion of a surface. Layers may, for example, be superimposed upon other layers to create a coating. While the wear-resistant and hydrophobic layers may be applied in any order, in general, the wear-resistant layer is desirably disposed between the substrate and the hydrophobic layer along at least some regions on the substrate surface. Additional layers may be similarly formed and used.

The average thickness of the coatings can be selected based upon the desired level of wear-resistance and/or hydrophobicity, which a person of ordinary skill with be able to determine based upon the application setting. In some embodiments, a coating can comprise a wear resistant layer having an average thickness of from about 1 nm to about 1 micron; in further embodiments, about 1 nm to about 5 microns, in further embodiments, from 1 nm to about 1 micron, in further embodiments, from about 1 nm to about 500 nm and, in further embodiments, from about 100 nm to about 200 nm. In some embodiments, a coating can comprise a hydrophobic layer having an average thickness from about 1 nm to about 5 microns, in further embodiments, from about 1 nm to about 1 micron; in further embodiments, from about 1 nm to about 500 nm and, in further embodiments, from about 200 nm to about 300 nm. A person of ordinary skill in the art will recognize additional ranges within the explicitly recited ranged are contemplated and within the present disclosure.

The coatings described herein can be desirably formed using specifically adapted plasma assisted ALD (“PALD”) and plasma enhanced CVD (“PECVD”) processing approaches. In general, the wear-resistant layer is formed using PALD and the hydrophobic layer is formed using adapted plasma enhanced PECVD. In one aspect, relative to non-plasma assisted approaches, the plasma assisted approaches described herein can be desirable for coating formation on temperature sensitive substrates such as electronic devices and woven and non-woven materials. In particular, in the plasma assisted processing approaches described herein, the plasma supplies energy to reactants/monomers to drive the deposition reaction so that deposition can be accomplished at lower temperatures relative to non-plasma assisted approaches. In other aspect, relative to non-plasma assisted approaches, the plasma assisted approaches described herein can allow for finer control and more uniformity of the deposited layers though control of the plasma properties.

In some embodiments, the adapted PALD and PECVD processes can desirably incorporate a capacitatively coupled plasma (“CCP”). Relative to inductively coupled plasmas (“ICP”), where the plasma is produced by electromagnetic induction, CCPs can be less dense and can result in more limited dissociation of reactants and monomers within the precursor composition. In general, the plasmas are formed by applying an electric field/electromagnetic field to gas phase precursor compositions comprising one or more reactant or monomer species. The characteristics of the field can significantly affect the composition, structure and/or properties of the deposited layers. The field can comprise a DC field, i.e., a continuous field, or AC field, such as a periodic field, e.g., an RF field. As used herein, a continuous field refers to a field that is generated when power is continuously supplied to the electrodes as either a DC current or an AC current. A pulsed field refers to a DC field or an AC field that is switched on and off by toggling the power to the electrodes, which may or may not be periodic, and which may be specified by a duty cycle as described below. The pulsing of an AC field generally refers to a gating of the periodic field at a lower frequency than the frequency of the AC field itself. The power of the resulting power generated by the field can be at least partially determined by the amplitude of the voltage applied to create the field. Additionally, it is noted that herein, as well as in the art, pulsed and continuous fields are used synonymously with pulsed and continuous plasmas.

In some embodiments, depositing a wear resistant layer and/or a hydrophobic layer can comprises depositing a layer covering essentially an entire substrate or a surface thereof. In some embodiments, depositing wear resistant layer and/or a hydrophobic layer can comprises depositing the layer on only a portion of a substrate. In some embodiments, a mask can be used to deposit a layer at one or more selected locations on a substrate. Masks are known in the art can be adapted for the processing purposes described herein. In some embodiments, the mask can be chemically or physically bonded to the surface with atomic level contact along the mask. In some application settings, a mask that is chemically or physically bonded to the substrate may not be desirable because removing the mask can involve etching with potentially corrosive compositions (relative to the composition of the substrate and/or coatings) and/or or further substrate cleaning due to residue left behind after the mask is removed. Mask that chemically or physically bond to the surface of the substrate can be formed and/or applied using methods well known in the art including, but not limited to, photoresist techniques and taping techniques.

In other embodiments, the mask can comprise a flat surface(s) that is(are) placed against the surface(s) of the substrate to cover a selected portion of a substrate such that the coating is substantially blocked from reaching covered portions of the substrate. The surface-to-surface contact can provide sufficient contact to prevent significant migration of layer deposition material past the mask. Such masks can be desirable in some application because their removal general requires the application of physical force to separate the mask from the substrate. Mask that do not chemically or physical bond to the surface of the substrate can be formed and/or applied using methods well known in the art including, but not limited to, stenciling techniques.

### PALD/PECVD Apparatus

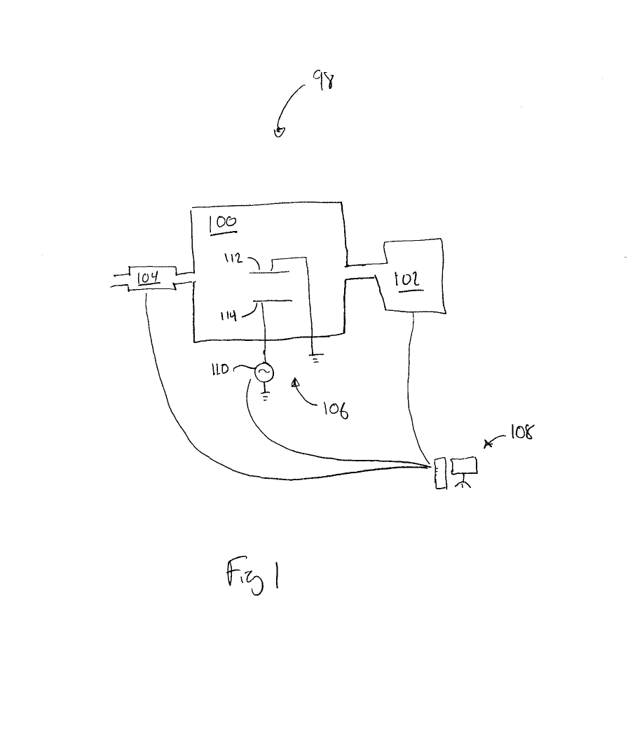

FIG. 1 is a schematic representation of a PALD/PECVD apparatus that can be used to form the coatings described herein. Referring to the figures, the PALD/PECVD apparatus comprises vacuum chamber 100, precursor deliver system 102, evacuation system 104, field generation system 106, and computer control system 108. Vacuum chamber 100 can have can any reasonable shape, including, but not limited to a cuboid or a cylindrical shape and can be formed from any suitable material, including but not limited to aluminum, stainless steel and carbon steel. The volume of the vacuum chamber can be selected based on a variety of factors including, but not limited to, the desired processing conditions, the size of the substrate or substrates (if simultaneous coating of a plurality of substrates is desired), and field power and the desired amount of precursor material to be used for a given deposition. In some embodiments, a vacuum chamber can have a volume of no more than about 1000 L, from about 5 L to about 1000 L or from about 20 L to about 500 L. In some embodiments of a PALD/PECVD apparatus, a heater can be coupled to vacuum chamber 100 to help maintain a constant temperature within vacuum chamber 100. The heater can be coupled to the interior or exterior of the vacuum chamber. In some embodiments, the heater can be a rope heater.

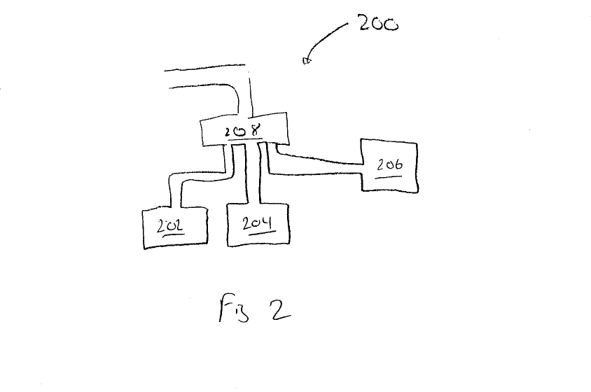

Precursor delivery system 102 can provide for delivery of precursor compositions into vacuum chamber 100. Precursor deliver system 102 can be configured to deliver precursor compositions comprising PALD reactants and/or PECVD monomers and, optionally, other carrier and/or activation gasses into vacuum chamber 100 at desired relative concentrations and flow rates. Carrier gases can include, for example, argon, nitrogen, and oxygen. Activator gasses can facilitate the PECVD polymerization process and can include, for example, ozone. In some embodiments, A PALD/PECVD apparatus can be configured with multiple precursor delivery systems such that each system delivers one or more PALD reactants or PECVD monomers and/or carrier gasses. FIG. 2 shows an embodiment of a precursor delivery system. Referring to the figure, precursor delivery system 200 comprises precursor sources 202, 204, carrier gas source 206 and mixing system 208. In one configuration, precursor sources 202, 204 can individually provide one of the two reactants for the PALD process. In another configuration, precursor sources 202, 204 can provide different monomer precursor compositions. Precursor composition sources 202, 204 can comprise precursor material provided in vapor or gas form to mixing system 208. Mixing system 208 comprises a manifold with independent flow control of each precursor source 202, 204 and carrier gas source 206 and can provide for desired relative concentrations of precursors and carrier gasses and to vacuum chamber 100. Evacuation system 104 can provide for evacuation of vapor/gas materials form the interior of vacuum chamber 100 and comprise a pump or the like. Evacuation system 104 can also help maintain a selected pressure within the reaction chamber.

The field generation system 106 provides the excitation for plasma generation from the precursor compositions. Field generation system 106 comprises power supply 110 and electrodes 112, 114. Power supply 110 can comprises a power supply capable of producing a field across electrodes 112, 114. Power supply 110 can be configured to produce fields having characteristics described below. During deposition, it is generally desirable for the substrate to be placed between electrodes 112, 114. In some embodiments, electrode 112 or 114 can comprise a substrate support. In some such embodiments, the substrate support can be coupled to a heating element to heat the substrate to aid deposition thereon.

Computer control system 108 can comprise a computing device to provide for automation of the processes described herein. Computer control system 108 is communicatively coupled to evacuation system 102 and 104 to independently control the flow of precursors and/or carrier gasses and/or activation gasses into and/or out of vacuum chamber 100. For example, in precursor delivery system 200, computer control system 108 can be communicatively coupled to mixing system 208 to independently control the flow for each precursor and carrier gas as well as the relative concentrations thereof. Computer control system 108 is also communicatively coupled to power supply 110 to control the flow and type of power delivered to electrodes, as well as the characteristics of the field thereby generated, as described above. In some embodiments, Computer control system 108 can comprise a computing device having a processor and accessible memory, such as a desktop computer or mobile computing device including, but not limited to, a laptop computer, a tablet computer, or mobile phone. The accessible memory of the computing device can comprise instructions that, when executed by the processor, allow for control of various components of the PECVD apparatus to automate the processes described herein.

As explained above, in some embodiments, the processes described herein can comprise a cleaning process and one or more deposition processes. In some embodiments, computer control system 108 can be configured to automate each of the process so that a user can place a substrate into PALD/PECVD apparatus 98 and, thereafter, the computer can configure the PALD/PECVD to perform the cleaning process and/or one or more of the deposition processes without human intervention.

The person of ordinary skill in the art will recognize that while a single embodiment of a combined PALD/PECVD apparatus is shown in FIG. 1, in other embodiments, separate apparatuses can be used to perform the PALD and PECDVD processing described herein.

### Processing

To form the improved coatings herein, adapted PALD and PECVD processes can be employed. In general, coating formation comprises an optional cleaning step, a wear resistant layer deposition step and a hydrophobic layer deposition step. The optional cleaning step can comprise cleaning the substrate to remove contaminants thereon. Subsequently, in some embodiments, the wear resistant layer can be deposited on the substrate and a hydrophobic layer can be deposited on the wear resistant layer. As described above, in some embodiments, the coatings of interest herein can comprise a wear resistant layer without a hydrophobic layer or a hydrophobic layer without a wear resistant layer. Although the processing approaches are described herein in relation to a coating comprising a wear resistant layer and a hydrophobic layer, a person of ordinary skill in the art will recognized that the individual descriptions relating to the deposition of either layer can be used to form the corresponding layer without the formation of the other.

Prior to deposition of the wear resistant layer or the hydrophobic layer, the substrate can be cleaned using a variety of approaches known in the art. In some embodiments, the substrate can be cleaned using appropriate solvents such as alcohols or dilute acids. In additional or alternative embodiments, the substrate can be cleaned using a plasma. For plasma cleaning, plasma activated species formed from oxygen and/or ozone can be particularly effective in removing organic contaminants from the surfaces of the substrate. For substrates comprising readily oxidizable material such as silver or copper, more inert precursors such as argon, nitrogen and/or helium can be used in a plasma cleaning process. Plasma cleaning of the substrate can be desirable because a PALD/PECVD apparatus configured to incorporate the processing approaches described herein can similarly be configured to perform plasma cleaning of the substrate in an automated process. For example, referring to FIG. 1, precursor delivery system 102 can be configured to deliver oxygen, ozone, argon, nitrogen, and/or helium (as well as other monomers for deposition of the polymer coating) into vacuum chamber 100 and computer control system 108 can be configured to adjust the parameters of field generation system 106. In operation, computer control system 106 would first configure precursor deliver system to deliver one or more of the aforementioned compounds into vacuum chamber 100 and configure field generation system 106 to provide the desired field (e.g., a continuous, RF field). After a desired time, computer control system 108 could reconfigure PECVD apparatus 98 to deposit the polymer coating as described below. In general, plasma cleaning is performed at a pressure of 50 milliTorr (“mTorr”) or higher using a plasma having a power density of about 0.001 W/L to about 0.5 W/L or greater. In some embodiments, subsequent to cleaning and prior to deposition of a wear resistant layer of hydrophobic layer, an outgassing process can be performed. Outgassing can involve evacuating the vacuum chamber to an outgassing pressure and maintaining the outgassing pressure for a desired amount of time. Outgassing can be particularly desirable for substrates comprising open cell structures.

Following optional cleaning of the substrate, the wear resistant layer can be deposited on the substrate using adapted PALD processing approaches. In some embodiments, PALD incorporates a continuous wave plasma to drive the deposition. During PALD processing, the PALD precursors can be sequentially pulsed into the plasma. The PALD processing parameters can be selected to form wear resistant layers having substantially no pin-hole structures that are well adhered to the underlying substrate.

The PALD processing approach involves layer formation using a half-reaction approach to obtain layers with atomic layer control. PALD uses gas phase precursors that are used to perform specific surface reactions. Two sequential reactants (one for each half reaction) are used to provide control through self-limitation of the reaction at each step. With respect to the wear resistant layers, a suitable primary precursor is generally an organometallic composition that can be represented by the formula MXₙ, where M is a metal or metalloid to be incorporated into the wear resistant layer, where X is a displaceable group and n indicates the stoichiometry of the compound. Without being limited by a theory, it is believed that when MXₙ is introduced into a plasma, it is ionized and/or radicalized such that such that M binds to a surface atom of the substrate while maintaining bonding to the Xₙ₋₁ groups. When an oxygen donating precursor such as water is introduced into the plasma at a second stage reaction step, the water is ionized and/or radicalized such that the precursor displaces HX, and effectively an M-OH group has been added to the surface that is then available to undergo another layer addition if desired, X′ is a group of the oxygen donating precursor. Nitrogen donating precursors behave analogously. Following a further purging and/or evacuation of the reactor, the sequential steps can be repeated over successive cycles to form a desired layer thickness.

For the metal/metalloid oxide and metal/metalloid nitride wear resistant layers of interest herein, suitable metal donating precursors can include, but are not limited to, metal/metalloid alkyl compounds, metal/metalloid alkoxide compounds, metal/metalloid cyclopentadienyl compounds and metal/metalloid beta-diketonate compounds. Metal/metalloid alkyl compounds are represented by the formula M(R)ₙ, wherein M is a metal or metalloid, each R is independently a straight or branched alkyl group having 1 to 20 carbon atoms, and n is the oxidation state of M. In some embodiments, each R can be, independently, a hydrogen, a methyl group, an ethyl group or a propyl group. In some embodiments, M can comprise Zn, Cd, Hg, B, Al, Ga, In, Si, Ge, Sn, Sb, Bi, and Te. Suitable metal/metalloid alkyl compounds can include, but are not limited to, Al(CH₃)₃ (which exists as a dimer Al₂(CH₃)₆), Zn(CH₃)₂, diisoporopyltellurium and the like.

Metal/metalloid alkoxide compounds are represented by the formula M(OR)ₙ, where M, R and n are defined as above. In some embodiments, (OR) can be a methoxy group, an ethoxy group, an isopropoxy group, an isobutoxy group, a sec-butoxy group, a tert-butoxy group or a tert-pentoxy group. In some embodiments, M can be Ti, Zr, Hf, V, Nb, Ta, Ni, Gd, B, Al, Si, Ge, or Pb. Suitable metal/metalloid alkoxide compounds can include, but not limited to, Al(OCH₂CH₃)₃, Hf(OC(CH3)₃)₄, Ti(OCH₃)₄, Ti(OCH₂CH₃)₄, Ti(OCH(CH₃)₂)₄ and the like.

Metal/metalloid cyclopentadienyl compounds are represented by the formula M[C₅R₅]ₙ, where M, R and n are defined as above. In some embodiments, [C₅R₅] can be a cyclopentadienyl group, a methylcyclopentadienyl group, a pentamethylcyclopentadienyl group, an ethylcyclopentadienyl group or isopropylcyclopentadienyl group. In some embodiments, M can be Cr, Mg, Ca, Sr, Ba, Sc, Y, La, Ti, Zr, Hf, Pr, Mn, Fe, Ru, Co, Ni, Pt, In, Er, and Lu. Suitable metal/metalloid cyclopentadienyl compounds can include, but are not limited to bis(cyclopentadienyl)chromium(II) and bis(pentamethylcyclopentadienyl)chromium(II).

Metal/metalloid beta-diketonate compounds are represented by the formula M(C₅O₂R₃)ₙ where M, R and n are defined as above. In some embodiments, (C₅O₂R₃) can be pentane-2,4-dionate; 1,1,1,5,5,5-hexafluoroacetylacetonate; 2,2,5,5-tetramethyl-3,5-heptanedionate; octane-2,4-dionate or 1-(2-methoxyethoxy)-2,2,6,6-tetramethyl-3,5-heptanedioate. In some embodiments, M can be MG, Ca, Sr, Ba, Sc, Y, La, Ti, Zr, Hf, V, Cr, Mn, Re, Fe, Ru, Os, Co, Rh, Ir, Ni, Pd, Pt, Cu, Ga, In or Pb. Suitable metal/metalloid beta-diketonate compounds include, but are not limited to, chromium(III) tris(2,2,6,6-tetramethyl-3,5-heptanedionate).

Suitable oxygen donating precursors of interest herein can include, but are not limited to, water vapor, hydrogen peroxide, alcohols represented by the formula ROH where R is defined as above, O₂, O₃ and NO₂. Suitable nitrogen donating precursors include, but are not limited to, NH₃, N₂H₄, N₂ and NO. A precursor composition may comprise one or more organometallic precursors or one or more oxygen or nitrogen donating precursors. For example, generally if hydrogen peroxide is used as an oxygen donating precursor, it is generally used in conjunction with water vapor.

As previously discussed, the PALD process described herein incorporates a plasma assisted processing approach. The field applied to the precursor compositions to generate the plasma can be a DC field or an AC field, e.g., a RF field. The DC field or AC field can be a continuous or pulsed field, and the pulsing can be described in terms of a duty cycle. However, for deposition of the wear resistant layer, continuous fields can be desirable because they generally form plasmas with larger power densities relative to pulsed fields, as discussed below. In some embodiments, an AC field (including an RF field) can have a frequency of between about 10 Hz to about 3 GHz; in further embodiments and, in further embodiments, from about 1 MHz to about 100 MHz. Commercial available AC (including RF) power generators generally operate at standard frequencies including, but not limited to, from about 50 Hz to about 60 Hz, 2 MHz, 13.56 MHz, and 40.68 MHz, and can be suitable power sources for the apparatuses and processes described herein. A person of ordinary skill in the art will recognize additional ranges of frequency within the explicitly disclosed ranges are contemplated and within the scope of disclosure. In some embodiments, it can be desirable to use a high frequency (i.e. greater than about 1 kHz) oscillating field. High frequency fields can be desirable because they allow for layer deposition onto non-conductive substrates. Additionally, factors such as deposition time, field operation mode (i.e., continuous or pulsed), plasma power density, precursor flow rate, working pressure, and temperature can all also affect the structure, composition and/or properties of the polymer coating. With respect to deposition time, a person of ordinary skill in the art will know how to select an appropriate deposition time to obtain a desired electrically insulating layer and hydrophobic layer thickness. Desirable field operation mode parameters, plasma power density parameters, pressures and temperatures are discussed below in relation to deposition of the individual wear resistant and hydrophobic layers.

For PALD of the wear resistant layer, it has been discovered that improved insulating layers can be formed from plasmas having relatively high power densities. Generally, higher power densities are associated with continuous fields and, therefore, in some embodiments, PALD can comprise using a continuous field to generate a plasma having a relatively high power density. It has been discovered that by incorporating plasmas having relatively high power densities, a wear resistant layer having reduced pin-hole structures can be obtained, translating into improved wear-resistance, electrical insulation and hydrophobicity.

As used herein, power density refers to the average power of the plasma divided by the volume of the vacuum chamber. The average power of the plasma can be defined as

$$〈 P 〉 = ( \frac{{t}_{on}}{{t}_{on} + {t}_{off}} ) 〈 {P}_{on} 〉 = D 〈 {P}_{on} 〉 ,$$

where tₒₙ is the time period during which power is supplied to the electrodes, t_{off} is the time period where no power is supplied to the electrode, [symbol] Pₒₙ [symbol] is average power supplied to the electrodes during tₒₙ and D is the duty cycle. For continuous wave plasmas, D=1 and [symbol] P [symbol] = [symbol] P_{CW} [symbol] , where [symbol] P_{CW} [symbol] is the average power of the continuous wave plasma. In some embodiments, for PALD of the wear resistant layer can comprise a continuous wave plasma having a power density of at least 0.2 watts per liter (“W/L”), or at least 3 W/L, or from about 1 W/L to about 100 W/L, or from about 1 W/L to about 50 W/L or from about 1 W/L to about 10 W/L. A person of ordinary skill in the art will recognize that additional ranges of power densities within the explicit ranges above are contemplated and are within the present disclosure.

For PALD of the insulating layer, in some embodiments, it can be desirable to perform the deposition above a target temperature and/or pressure. Performing PALD at above a target temperature and pressure can be desirable with respect to uniformity of deposited layer and the repeatability of the results. In some embodiments, the pressure can be maintained above a target value by monitoring the pressure inside the vacuum chamber and adjusting the flow the precursor composition into the vacuum chamber to help maintain a desired pressure. In some embodiments, the temperature can be regulated by a thermostat coupled to a heater as shown in FIG. 1. In some embodiments, PALD of the wear resistant layer can be performed using a target pressure of about 100 millitorr (“mTorr”) to about 10 Torr; in further embodiments, from about 100 mTorr to about 2 Torr, from about 200 mTorr to about 600 mTorr; and, in further embodiments, from about 350 mTorr to about 450 mTorr. In some embodiments, PALD of the wear resistant layer can be performed at a target temperature of from about 15° C. to about 200° C.; in further embodiments, from about 20° C. to about 150° C.; and in further embodiments; from about 30° C. to about 100° C. A person of ordinary skill in the art will recognize additional ranges of pressure and temperature within the explicitly disclosed ranges are contemplated and within the present disclosure.

In the PALD process, the precursors are discretely pulsed into the reaction chamber to allow for deposition of the wear resistant layer. In generally, the precursors are pulsed into the reaction chamber so that the plasma is maintained (i.e., not extinguished) during the PALD process. A PALD precursor pulse cycle can comprise a pressurization phase and a soak phase and an evacuation phase. In some embodiments, the plasma is not extinguished between pulses, which can increase the efficiency of the deposition process relative to re-igniting the plasma with each precursor pulse. The number pulse cycles can be selected based on the desired thickness of the deposited layer, where a larger number of cycles can correspond to a thicker hydrophobic layer and a smaller number of cycles can correspond to a thinner hydrophobic layer. For the PALD process, at least 2 pulse cycles are used, one corresponding to the metal/metalloid donating precursor and the other corresponding to the oxygen donating precursor. In some embodiments, the number of pulse cycles can be between 2 and 10,000; in further embodiments, between 2 and 1000; in further embodiments, between 2 and 100; in further embodiments, between 2 and 75; and, in further embodiments, between 2 and 50. A person of ordinary skill in the art will recognize additional ranges within the explicitly disclosed ranges are contemplated and within the present disclosure.

The pressurization phase can comprise pressurizing the vacuum chamber to a target pressure. In some embodiments, the pressurizing phase can also operate as a purging mechanism to purge the chamber of the previous precursor composition. In some such embodiments, the flow of precursor composition through the vacuum chamber can be maintained at the target pressure (or a different pressure) for a given time period to help purge the vacuum chamber with the precursor composition. In general, the target pressure can be selected based on the processing conditions desired for the subsequent soak phase which comprise PALD. In some embodiments, the target pressure can be from about 0.02 mTorr to about 10 Torr, in some embodiments, from about 100 mTorr to about 10 Torr; in further embodiments, from about 100 mTorr to about 1 Torr. A person of ordinary skill in the art will recognize that additional ranges within the explicit ranges above are contemplated and are within the present disclosures.

The soak phase can comprise isolating the vacuum chamber from reactant flow into and out of the chamber. In some embodiments, while the reactant components (i.e., organometallic and oxygen/nitrogen donating composition) of the precursor composition are prevented from flowing into the chamber, the carrier gas component is allowed to flow into the chamber during the soak period to maintain a target pressure. The duration of the soak phase can be selected relative to the initial pressure at the beginning of the soak phase. In particular, the combination of selected initial pressure at the outset of the soak phase and selected soak phase duration, in combination with other parameters, can affect the quality of the ultimately formed layer with respect to the number and size of pin-hole structures. For example, soak times that are too short can lead to wear resistant layers that have increased pin-hole structures due to incomplete reaction of the PALD precursors. In some embodiments, the soak time can be between about 0.1 seconds to about 10 minutes; in further embodiments, from about 1 second to about 5 minutes; in further embodiments, from about 1 second to about 2 minutes and in further embodiments; from about 1 seconds to about 30 seconds. A person of ordinary skill in the art will recognize additionally ranges of soak period durations within the explicitly disclosed ranges are contemplated and within the scope of the disclosure.

The evacuation phase comprises evacuating the vacuum chamber to remove a portion of the plasma material prior to the next pressurization phase. In some embodiments, the evacuation phase comprises isolating the vacuum chamber from flow into the chamber and evacuating the chamber to a target pressure. In some embodiments, the target pressure can be between about 0.01 mTorr to about 400 mTorr; in further embodiments, between about 0.01 mTorr to about 200 mTorr; and in further embodiments, between about 0.1 mTorr to about 100 mTorr. A person of ordinary skill in the art will recognize additional ranges within the explicitly claimed rages are contemplated and within the present disclosure.

Following deposition of the wear resistant layer, the hydrophobic layer can be deposited using adapted PECVD processing approaches. The PECVD approaches described herein involve the introduction of polymerizable precursor compositions into a pulsed or continuous plasma to drive the polymerization reaction. The plasma can be a continuous wave plasma or a pulsed plasma, although a pulsed plasma can be desirable as described below. In some embodiments, the precursor compositions can be pulsed into the plasma.

The PECVD plasma driven polymer vapor deposition can be useful for monomers that are susceptible to radical polymerization since the plasma can activate the compounds to induce polymerization. In particular, the monomers are introduced as a gas into the plasma, which results in energetic species, such as electrons, ions or photons, in the gas phase, consequently effecting the breaking of chemical bonds and thus creating free radicals that then are absorbed by the surface of the substrate and/or bond together and/or polymerize. For example, vinyl and polyether polymers can be synthesized through radical and/or ionic mechanisms, and correspondingly, vinyl and epoxide monomers, respectively, can be suitable precursors for the PECVD polymer deposition method. Vinyl compounds can be represented by the formula R₁R₂C═CR₃R₄, where each R individually can be hydrogen, halogen, an organic group, such as a hydrocarbon group or substituted hydrocarbon group. Epoxide compounds can be represented by the formula:

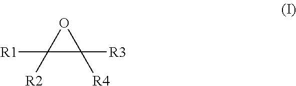

where each R can be individually selected as described above. Without being limited by a theory, while both vinyl and epoxide monomers can be used in the PECVD processes described herein, it is believed that they polymerize through different mechanisms. In particular, it is believed that vinyl monomers can polymerize breaking the C═C double bond structure to from a radical C—C single bond structure. Epoxide monomers, it is believed, polymerize through ring opening accomplished by breaking an O—C bond to form a O—C—C radical structure.

The organic groups can comprise linear or branched (saturated or unsaturated) hydrocarbon chains generally with 1 to 20 carbon atoms, and in some embodiments 1-8 carbon atoms, and in further embodiments 2-6 carbon atoms. Fluorine substituted moieties can be desirable due to the resulting hydrophobic nature of fluorinated polymers, especially perfluorinated, i.e., compositions in which hydrogens are globally substituted with fluorine. Thus, for example, alkenes, such as fluorinated alkenes are suitable precursors. In some embodiments, for epoxide monomers, R₁-R₃ can be hydrogen and R₄ can be represented by the formula —CH₂(CF₂)ₙCF₃, where n is 1 to 20. In such embodiments, suitable epoxide precursors can include, but are not limited to, 3-(perfluorohexyl)propyl epoxide and (perfluorooctyl)propyl epoxide and

For vinyl monomers, acrylate based compositions can be used as precursors, which have a general composition in which R₁ above is —COOR₅, where R₅ can be hydrogen (acrylic acid), or a hydrocarbyl group having between 1 and 20 carbon atoms. Specific embodiments of acrylate monomers include, for example, methacrylates (R₅=—CH₃), methyl acrylates (R₂=—CH₃), methyl metacrylates (R₂=—CH₃ and R₅=—CH₃), ethyl acrylates (R₅-—CH₂CH₃), buytl methacrylates (R₂=—(CH₂)₃CH₃ and R₅=—CH₃), partially fluorinated versions thereof, perfluorinated versions thereof and the like. In some embodiments, suitable vinyl precursors can include, but are not limited to, 1H, 1H, 2H, 2H-tridecafluorooctyl methacrylate and 1H, 1H, 2H, 2H-perfluorodecyl acrylate.

For PECVD of the hydrophobic layer, it has been surprisingly discovered that by generating a plasma having a relatively low power density and by pulsing the precursor composition into the vacuum chamber of a PECVD apparatus, polymer particles can be deposited and fused to the electrically insulating layer or substrate. PECVD processing for deposition of hydrophobic layers using pulsed plasmas and pulsed precursor compositions is described in co-pending U.S. patent application Ser. No. 13/838,612 to Storey et al., entitled “Apparatus And Methods For Plasma Enhanced Chemical Vapor Deposition Of Polymer Coatings” and incorporated herein by reference. For PECVD of hydrophobic layers, the plasma can have an average power density of between 0.001 W/L to about 10 W/L; in other embodiments, from about 0.001 W/L to about 1 W/L; and in further embodiments, from about 0.001 W/L to about 0.1 W/L. A person of ordinary skill in the art will recognize additional ranges of power density within the explicitly disclosed ranges are contemplated and within the scope of disclosure. In general, plasmas having relatively low power densities are associated with pulsed fields and, therefore, in some embodiments, PECVD of a hydrophobic layer can comprise deposition using a pulsed field. In some embodiments, the gating of the field, i.e., the period of field bursts, can be described in terms of a frequency from about 5 kHz to about 250 kHz; in other embodiments, from about 10 kHz to about 150 kHz; and in further embodiment, from about 25 kHz to about 105 kHz. In some embodiments, the field can be pulsed with a duty cycle of about 0.5% to about 20%; in other embodiments, from about 0.5% to about 5%; in other embodiments from about 1% to about 4%; and, in further embodiments, from about 2% to about 3%. A person of ordinary skill in the art will recognize additionally ranges of frequencies and duty cycles within the explicitly claimed ranges are contemplated and within the present disclosure.

With respect to pulsing, the PECVD precursors can be pulsed as described above with respect to the PAPD processing, with each pulse comprising a pressurization phase, a soak phase and an evacuation phase. As described above with respect to PALD, in general, the precursors are pulsed into the reaction chamber so that the plasma is maintained (i.e., not extinguished) during the PECVD process. In some embodiments, the timing of the PEPCVD process can be started soon after the PALD process so that the plasma is effectively maintained throughout the PALD and PECVD processes. Although, in other embodiments, the plasma is extinguished between the PALD and PECVD processes. The number pulse cycles can be selected based on the desired thickness of the deposited hydrophobic layer, where a larger number of cycles can correspond to a thicker hydrophobic layer and a smaller number of cycles can correspond to a thinner hydrophobic layer. In some embodiments, the number of pulse cycles can be between 2 and 10,000; in further embodiments, between 2 and 1000; in further embodiments, between 2 and 100; in further embodiments, between 2 and 75; and, in further embodiments, between 2 and 50. A person of ordinary skill in the art will recognize additional ranges within the explicitly disclosed ranges are contemplated and within the present disclosure.

With respect to the pressurization phase, the target pressure can be selected based on the processing conditions desired for the subsequent soak phase. In some embodiments, the target pressure can be from about 0.02 mTorr to about 500 mTorr; in further embodiments, from about 0.01 mTorr to about 200 mTorr; in further embodiments, from about 0.1 mTorr to about 100 mTorr. A person of ordinary skill in the art will recognize that additional ranges within the explicit ranges above are contemplated and are within the present disclosures.

With respect to the soak phase, without being limited by a theory, it is believed processing parameters comprising relatively low power density plasmas and pulsed precursor compositions can be desirable to help quench polymer particle growth such that deposited layer comprise a particulate polymer layer. The duration of the soak phase can be selected relative to the initial pressure at the beginning of the soak phase. In some embodiments, the duration of the soak phase can affect particle size, with longer soak times corresponding to the production polymer layers having polymer particles with larger average primary particles sizes and shorter soak times corresponding to the production of polymer layers having polymer particles with smaller average primary particle sizes. In particular, the combination of selected initial pressure at the outset of the soak phase and selected soak phase duration, in combination with other parameters, can affect polymer particle size. In some embodiments, the soak time can be between about 0.1 seconds to about 10 minutes; in further embodiments, from about 0.1 seconds to about 10 minutes; in further embodiments, from about 1 second to about 5 minutes; in further embodiments, from about 1 second to about 2 minutes and in further embodiments; from about 1 seconds to about 30 seconds. A person of ordinary skill in the art will recognize additionally ranges of soak period durations within the explicitly disclosed ranges are contemplated and within the scope of the disclosure.

With respect to the evacuation phase, while not being limited by a theory, it is believed that evacuation can help quench the particle formation process by lowering the monomer concentration in the vacuum chamber and, in combination with the pressurization phase parameters and soak phase parameters, help to control the range of polymer particle sizes obtained during polymer particle layer formation. In some embodiments, the evacuation phase comprises isolating the vacuum chamber from flow into the chamber and evacuating the chamber to a target pressure. In some embodiments, the target pressure can be between about 0.01 mTorr to about 400 mTorr; in further embodiments, between about 0.01 mTorr to about 200 mTorr; and in further embodiments, between about 0.1 mTorr to about 100 mTorr. A person of ordinary skill in the art will recognize additional ranges within the explicitly claimed ranges are contemplated and within the present disclosure.

In some embodiments, it can be desirable to maintain the plasma through each pulse cycle and between cycles for both the PAPD and PECVD processes. It can be more efficient to maintain the plasma rather than letting it extinguish and re-igniting the precursor composition during a subsequent pulse cycle to re-establish the plasma. However, in some embodiments, desirable coatings can still be deposited if the plasmas is extinguished during a pulse cycle and/or between pulse cycles and/or between PAPD and PECVD processing.

### EXAMPLES

### Example 1 Performance of Coatings on Circuit Boards

This Example demonstrates the electrical insulation performance and hydrophobic performance of the coatings described herein on a circuit board substrate. The coating comprises a wear resistant layer and a hydrophobic layer formed using the adapted PEALD and PECVD processing approaches described herein.

To demonstrate performance, two samples were formed. The substrates comprised a Datak 12-612B circuit board obtained from a retail supplier. Each circuit board comprised 2 copper traces, approximately 2 mm across by 30 mm long and 2 mm apart on one side. Prior to coating deposition, the circuit boards were initially cleaned by wiping them down with isopropyl alcohol (“IPA”). The circuit boards were then subjected to a plasma cleaning process. To plasma clean a circuit board, it was placed in a vacuum chamber of a PEAPD/PECVD apparatus and the vacuum chamber was evacuated to about to about 0.5 mTorr. The chamber was then heated with external rope heaters to 45° C. and the temperature was held constant for the subsequent coating deposition processes. When the vacuum chamber had stabilized in both temperature and pressure, oxygen was bled into the chamber until the pressure stabilized at 50 mTorr±2 mTorr. When the chamber had again stabilized in temperature and pressure, the circuit board was for 5 minutes with a plasma having an average power of 500 W and formed from the oxygen using a continuous wave RF field at 13.56 MHz. After the etch, the chamber was again evacuated to 5 mTorr and a wear resistant layer was deposited.

The wear resistant layer was deposited using PALD as described herein using a continuous wave 13.56 MHz RF field having an average power of 50 W to generate the plasma. The power density of the plasma was about 10 W/L. The wear resistant layer was deposited by sequentially pulsing Al₂(CH₃)₆ (trimethylaluminum) and vaporized water into the reaction chamber of the PALD/PECVD apparatus. Both precursors were delivered into the reaction chamber using an argon carrier gas, flowing at 20 SCCM constantly. Each pulse comprised a 0.1 second pressurization phase, a 10 second soak phase and a 20 second evacuation phase. The wear resistant layer was deposited over 100 cycles (sample 1) or 200 cycles (sample 2), which each cycle comprising a trimethylaluminum pulse and a waver vapor pulse. During deposition of wear resistant layer, the chamber pressure was maintain at a pressure of 350 mTorr or greater and the plasma was continuously generated. After deposition of the wear resistant layer, the chamber was evacuated to 0.5 mTorr and a hydrophobic layer deposition was started.

The hydrophobic layer was deposited using PECVD as described herein using a pulsed 13.56 MHz RF field having an average power density of 0.15 W/L to generate the plasma. The plasma was pulsed with a period of 10 milliseconds (“ms”), pulse width of 500 microseconds, and a delay of 500 ms, which corresponded to a duty cycle of 2%. Vaporized 1H, 1H, 2H, 2H-tridecafluorooctyl methacrylate (“TDFOM”) was pulsed into the chamber to form the coating. Each pulse comprised a pressurization phase having a target pressure of 1 Torr, a soak phase having a duration of 30 seconds and an evacuation phase having a target pressure of 400 mTorr. The hydrophobic layer was deposited over 240 minutes, corresponding to 200 monomer pulses. After deposition of the hydrophobic layer, the chamber was vented to the atmosphere and the circuit board was removed. Ellipsometry measurements of sample 1 showed the total coating thickness was between 300 nm and 500 nm and ellipsometry measurements of sample 2 showed the total coating thickness was between 400 nm and 600 nm.

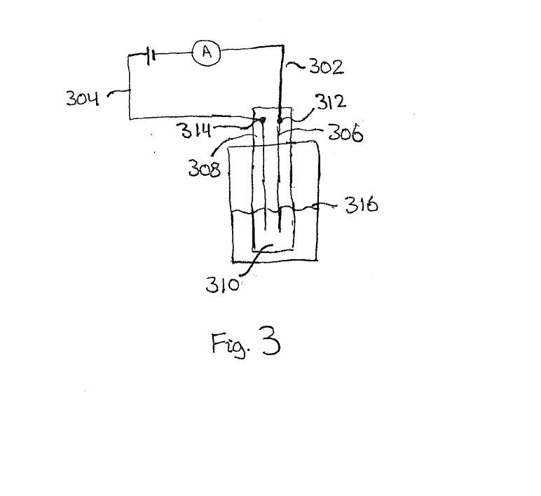

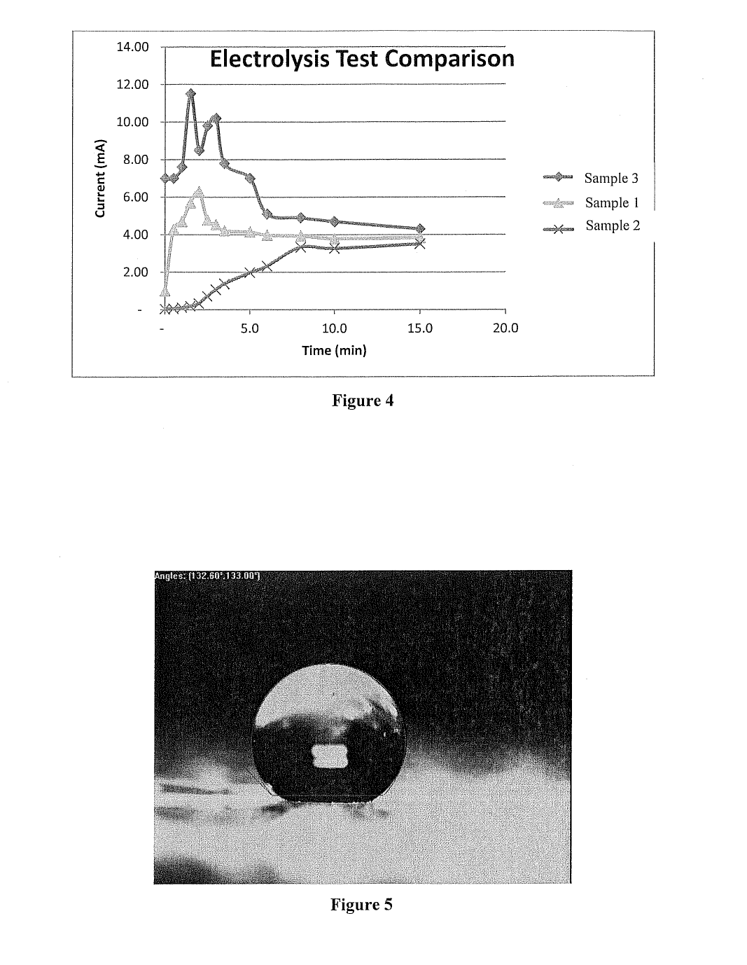

To test the electrical insulation performance of the samples, after coating formation, an 18 gauge wire was soldered to each end of the two traces of each circuit board of sample 1 and sample 2. The wires were subsequently connected to a Tenma Laboratory DC Power Supply model 72-2005 (3 A, 20V max) power supply with one wire connected to the positive terminal and the other wire connected to the negative terminal. A third sample (sample 3), comprised Datak 12-612b circuit board, as purchased (i.e., no coating), and was similarly connected to a power supply as described above with respect to samples 1 and 2. The samples were then placed in 20 mm of tap water such that the wire trace attachment points where not submerged. A schematic depiction of the electrolysis test setup is displayed in FIG. 3. Referring to the figure, wires 302, 304 are respectively attached to traces 306, 308 of the circuit board 310 at attachment points 312, 314 which are above water level 316. Subsequently, the power supply was turned on, set at a constant voltage of 4.5 V and the increase in current passed between the 2 traces of each board via the water was measure over time at 30 second intervals. FIG. 4 is a graph displaying plots of the current versus time for samples 1-3. Referring to the figure, after 15 minutes, sample 3 (no coating) never passed less than 4 mA and went as high as 11.5. Sample 1 (100 cycle PECVD) and sample 2 (200 cycle) only reached a peak of 6.3 mA and 3.5 mA, respectively, and both stabilized below 4 mA.

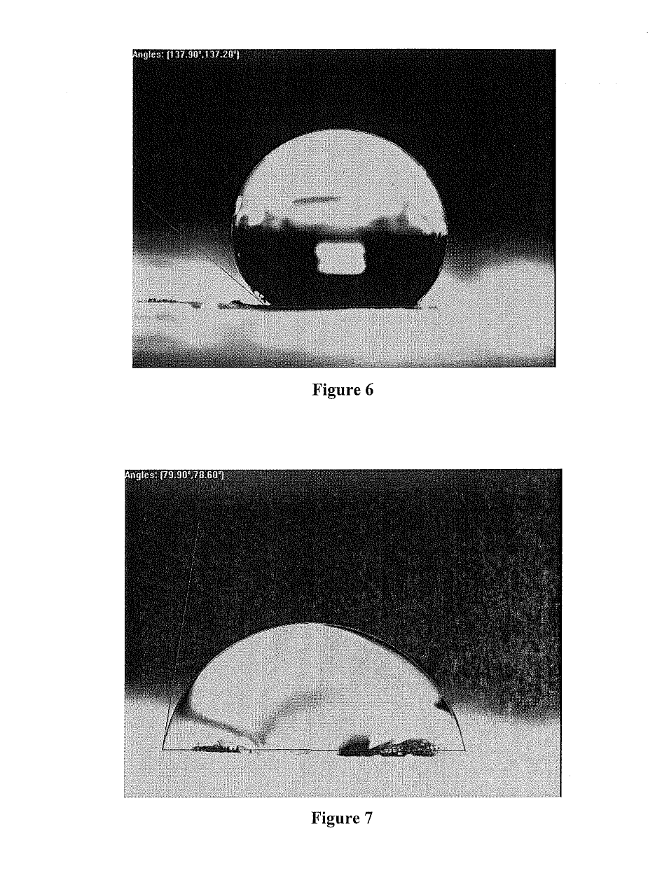

To test the hydrophobicity of coatings, goniometric analysis of samples 1-3 were performed using a VCA OPTIMA S goniometer from AST Products, Inc. (Billerica, Mass.). As discussed above, goniometric analysis measures the contact angle of a water droplet on the surface of the substrate. Photographic images of samples 1-3, obtained during goniometric analysis, are shown in FIGS. 5-7, respectively. The contact angle was measured to be about 133°, 137.5° and 79° for samples 1-3 respectively.

### Example 2 Performance of Coatings on Woven Materials

This Example demonstrates the hydrophobic performance of the coatings described herein on a woven material substrate. The coating comprises a wear resistant layer and a hydrophobic layer formed using the adapted PEALD and PECVD processing approaches described herein.

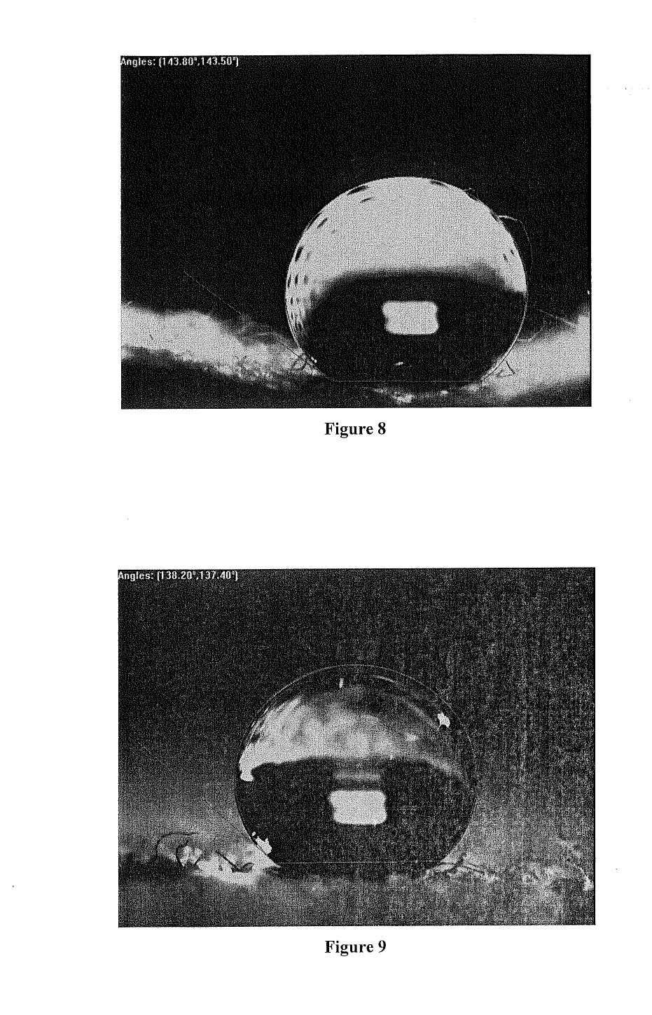

To demonstrate hydrophobic performance, a coating comprising a wear resistant layer and hydrophobic layer was deposited on a woven material substrate as described in Example 1. The substrate comprised a square of woven 100% cotton. The wear resistant layer was deposited over 100 cycles. After deposition, goniometric analysis was performed on the coated substrate as well as on a control sample comprising an un-treated square of woven 100% cotton. FIG. 8 is a photographic image of the coated substrate and demonstrates a water contact angle of about 143.5°, which also represented the increase in contact angle relative to un-treated sample.

### Example 3 Performance of Coatings on Non-Woven Materials

This Example demonstrates the hydrophobic performance of the coatings described herein on a non-woven material substrate. The coating comprises a wear resistant layer and a hydrophobic layer formed using the adapted PEALD and PECVD processing approaches described herein.

To demonstrate performance, a coating comprising a wear resistant layer and hydrophobic layer was deposited on a non-woven material substrate as described in Example 1. The substrate comprised a commercially available paper towel. The wear resistant layer was deposited over 100 cycles. After deposition, goniometric analysis was performed on the coated substrate as well as a control sample comprising an un-treated paper towel. FIG. 9 is a photographic image of the coated substrate and demonstrates a water contact angle of about 138°, which also represented the increase in contact angle relative to the un-treated sample.

The specific embodiments above are intended to be illustrative and not limiting. Additional embodiments are within the broad concepts described herein. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

1. A method for forming a coating on a substrate, the method comprising:
sequentially exposing a substrate to an organometallic reactant and a dielectric forming reactant in the presence of a first plasma to form a wear resistant layer on a surface of the substrate, wherein the dielectric forming reactant is an oxygen donating or nitrogen donating reactant and
reacting a vinyl monomer or epoxide monomer in the presence of a second plasma and the substrate comprising the wear resistant layer to form a hydrophobic polymer layer on the dielectric layer.

2. The method of claim 1 wherein the first plasma is a continuous wave plasma having an average energy density of 1 W/L to 50 W/L.

3. The method of claim 1 wherein the organometallic reactant and dielectric forming reactant are pulsed into the vacuum chamber and wherein each pulse comprises a pressurization phase, a soak phase, and an evacuation phase;
wherein the pressurization phase comprises introducing a precursor into the reaction chamber until a target pressurization pressure is reached;
wherein the soak phase comprises isolating the reaction chamber for a target duration of time; and
wherein the evacuation phase comprises the vacuum chamber to a target evacuation pressure.

4. The method of claim 3 wherein the target pressurization pressure is between about 0.02 mTorr to about 10 Torr, wherein the target duration of time is from about 0.1 seconds to about 10 minutes and wherein the target evacuation pressure is 0.01 mTorr to about 400 mTorr.

5. The method of claim 1 wherein the organometallic reactant comprises a metal/metalloid alkyl compound or a metal/metalloid alkoxide compound.

6. The method of claim 5 wherein the organometallic reactant is selected from the group consisting of Al₂(CH₃)₆, Zn(CH₃)₂, Al(OCH₂CH₃)₃, Hf(OC(CH3)₃)₄, Ti(OCH₃)₄, Ti(OCH₂CH₃)₄, and Ti(OCH(CH₃)₂)₄.

7. The method of claim 6 wherein the organometallic reactant comprises a metal/metalloid cyclopentadienyl compounds or a metal/metalloid beta-diketonate compounds.

8. The method of claim 7 wherein the organometallic reactant is selected from the group consisting of bis(cyclopentadienyl)chromium(II), bis(pentamethylcyclopentadienyl)chromium(II), and chromium(III) tris(2,2,6,6-tetramethyl-3,5-heptanedionate).

9. The method of claim 1 wherein the dielectric forming reactant is an oxygen donating reactant.

10. The method of claim 1 wherein the dielectric forming reactant is a nitrogen donating reactant.

11. The method of claim 1 wherein the second plasma is a pulsed plasma having an average power of 0.001 W/L to about 10 W/L.

12. The method of claim 11 wherein the plasma is pulsed with a duty cycle of between 1% and 20%.

13. The method of claim 1 wherein the vinyl monomer or epoxide monomer is pulsed into the vacuum chamber and wherein each pulse comprises a pressurization phase, a soak phase, and an evacuation phase;
wherein the pressurization phase comprises introducing a precursor into the reaction chamber until a target pressurization pressure is reached;
wherein the soak phase comprises isolating the reaction chamber for a target duration of time; and
wherein the evacuation phase comprises the vacuum chamber to a target evacuation pressure.

14. The method of claim 13 wherein the target pressurization pressure is between about 0.02 mTorr to about 500 mTorr, wherein the target duration of time is between about 0.01 seconds to about 10 minutes and wherein the target evacuation pressure is between about 0.01 mTorr to about 400 mTorr.

15. The method of claim 1 wherein the monomer is a vinyl monomer represented by the formula R₁R₂C═CR₃R₄, where R₂, R₃, R₄ individually comprise a hydrogen or an organic group comprising a hydrocarbon chain with 1 to 20 carbon atoms, and R₁ is represent by the formula —COOR₅, where R₅ is a hydrogen, or a perfluorinated hydrocarbyl group having between 1 and 20 carbon atoms.

16. The method of claim 1 wherein the monomer is an epoxide monomer represented by the formula, 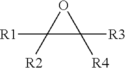
where R₂, R₃, R₄ individually comprise a hydrogen or an organic group comprising a hydrocarbon chain with 1 to 20 carbon atoms and R1 is represented by the formula —CH₂(CF₂)ₙ CF₃, where n is between 1 and 20.

17. A substrate comprising a transparent coating, the coating comprising:
a wear resistant layer comprising a metal/metalloid oxide or a metal/metalloid nitride;
a hydrophobic layer disposed on top the wear resistant layer, the hydrophobic layer comprising fused polymer particles having an average primary particle diameter of from about 20 nm to about 100 microns.

18. The coated substrate of claim 17 wherein the wear resistant layer and the hydrophobic layer each have a thickness of from about 1 nm to about 5 microns.

19. The coated substrate of claim 17 wherein the hydrophobic layer has a water contact angle of between about 100° to about 150°.

20. The coated substrate of claim 17 wherein the wear resistant layer comprises a metal/metalloid oxide selected from the group consisting of aluminum oxide, chromium oxide, titanium oxide, zirconium oxide.

21. The coated substrate of claim 17 wherein the wear resistant layer comprises a metal/metalloid nitride selected from the group consisting of aluminum nitride, hafnium nitride and chromium nitride.

22. The coated substrate of claim 17 wherein the substrate comprises an electronic device.

23. The coated substrate of claim 22 wherein the electronic device comprises a display and wherein the coating is deposited over at least a portion of the display.

24. The coated substrate of claim 23 wherein the electronic device comprises a mobile computing device.

25. The coated substrate of claim 17 wherein the substrate comprises a woven or non-woven fabric.
